(19) United States
(12) Patent Application Publication
(10) Pub. No.: US 2003/0107009 A1
(43) Pub. Date: Jun. 12, 2003

(54) Electron beam exposure apparatus and electron beam exposure method

(75) Inventor: Hitoshi Tanaka, Tokyo (JP)

Correspondence Address: David L. Fehrman, Morrison & Foerster LLP, 35th Floor, 555 W. 5th Street, Los Angeles, CA, 90013, US

(73) Assignee: ADVANTEST CORPORATION, Tokyo (JP)

(21) Appl. No.: 10/338,620

(22) Filed: Jan. 8, 2003

Related U.S. Application Data
(63) Continuation of application No. PCT/JP01/09359, filed on Oct. 24, 2001.

(30) Foreign Application Priority Data
Nov. 1, 2000 (JP) 2000-335158

(51) Int. Cl. H01J 37/302

(52) U.S. Cl. 250/492.23

(57) ABSTRACT

An electron beam exposure apparatus characterized by comprising an electron gun producing an electron beam, a first shaping member for shaping the cross-sectional shape of the electron beam, a second shaping member serving as a splitting member having a splitting part including splitting openings for splitting the electron beam into electron beams of different shapes, and a blocking member for blocking at least one of the electron beams.

The present application is a continuation application of PCT application No. PCT/JP01/09359 filed on Oct. 24, 2001. The present application claims priority from a Japanese Patent Application No. 2000-335158 filed on Nov. 1, 2000, the contents of which are incorporated herein by reference.

### BACKGROUND OF THE INVENTION

A conventional electron beam exposure apparatus includes an electron gun for producing an electron beam, a first slit which shapes the electron beam, and a second slit which shapes further a cross-sectional shape of the electron beam shaped by the first slit unit into a shape in which the electron beam is to be irradiated on a wafer. The second slit includes an opening to shape the irradiated electron beam and shapes the electron beam into a desired shape by allowing a part of an electron beam irradiated on the second slit to pass through the opening and blocking remaining part of the electron beam.

With high-densification of semiconductor devices in recent years, a width of wirings or the like of the semiconductor devices have become very narrow and the shape of exposure pattern to form the wiring or the like is required to be very accurate. However, in conventional electron beam exposure apparatuses, because most of the electron beam which has passed through the first slit is irradiated on the second slit, there has been a problem that the shape of the opening at the second slit is deformed by heat quantity of the irradiated electron beam. And because the shape of the electron beam, which is to be irradiated on the wafer, is deformed due to the deformation of the shape of the opening, it is very difficult to shape a desired exposure pattern.

### SUMMARY OF THE INVENTION

Therefore, it is an object of the present invention to provide an electron beam exposure apparatus which overcomes the foregoing issues in the related art. This object is achieved by combinations described in the independent claims. The dependent claims define further advantageous and exemplary combinations of the present invention.

In order to accomplish these purposes, according to the first aspect of the present invention, an electron beam exposure apparatus for exposing a pattern to a wafer using an electron beam is provided. The electron beam exposure apparatus includes an electron beam producing unit which produces the electron beam, a splitting member having splitting part with a plurality of splitting openings which split the electron beam into a plurality of electron beams of different shapes, and a blocking member which blocks at least one of the plurality of electron beams.

On another occasion, the electron beam exposure apparatus may include further a shaping member having a shaping opening which shapes the electron beam produced at the electron beam producing unit into a rectangular shape, and the splitting member may split the electron beam shaped into rectangular shape. Or the splitting part may split further the electron beams which are not blocked by the blocking member out of the plurality of electron beams. The blocking member may include a passing opening which allows the electron beams which is to be irradiated on a wafer out of the plurality of electron beams to pass through the passing opening. The electron beam producing unit may produce a plurality of electron beams, the splitting member may respectively have splitting parts in areas on which the plurality of electron beams in the splitting member is irradiated, and the blocking member may have a plurality of passing openings in areas on which a plurality of split electron beams, corresponding to a plurality of electron beams produced at the electron beam producing unit, are irradiated.

According to the second aspect of the present invention, an electron beam exposure method for exposing a pattern to the wafer using the electron beam is provided. The electron beam exposure method includes the steps of producing the electron beam, splitting the electron beam into a plurality of electron beams of different shapes, blocking at least one of the plurality of electron beams.

This summary of invention does not necessarily describe all necessary feature so that the invention may also be a sub-combination of these described features.

### BRIEF DESCRIPTION OF THE DRAWINGS

FIG. 1 shows an electron beam exposure apparatus 100 according to an embodiment of the present invention.

FIG. 2 shows a first shaping member 14, a second shaping member 22, a shaping-blocking member 500 and the shape of an electron beam passing through each of the members.

FIG. 3 shows other embodiments of the second shaping member 22.

### DETAILED DESCRIPTION OF THE INVENTION

An embodiment of the present invention will be described hereinafter with reference to the drawings.

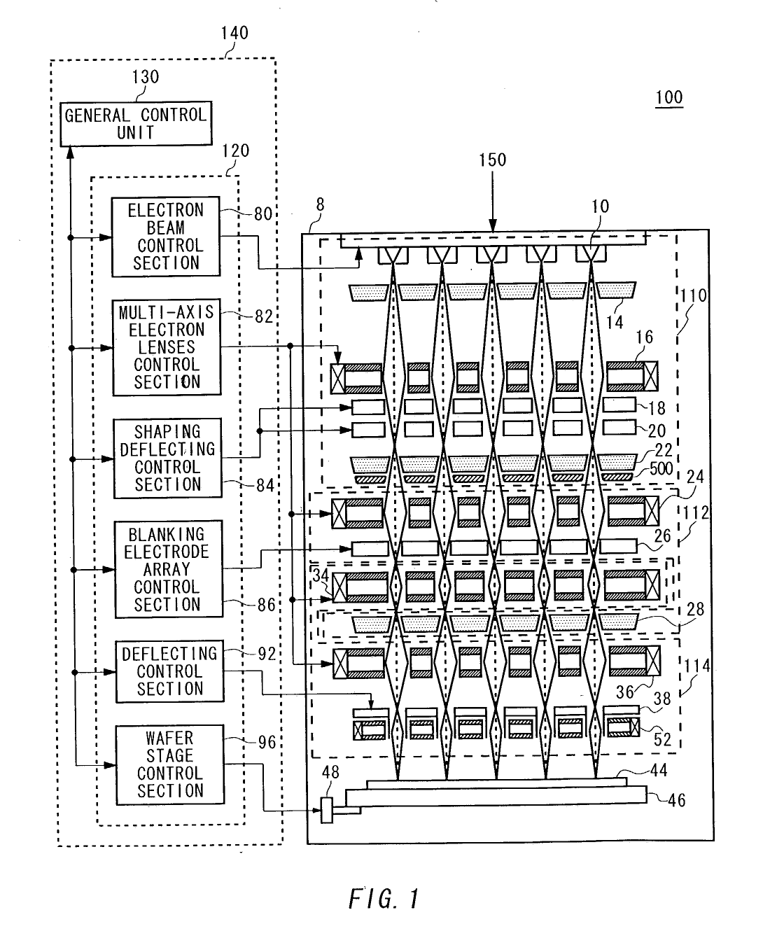

FIG. 1 shows an electron beam exposure apparatus 100 according to an embodiment of the present invention. The electron beam exposure apparatus 100 includes an exposing unit 150 for performing an exposure process of an electron beam on a wafer 44 and a control system 140 for controlling the operation of elements included in the exposing unit 150.

The exposing unit 150 includes an electron beam shaping unit 110 for producing a plurality of electron beams and shaping the cross-sectional shape of the electron beam into desired shapes inside a casing 8, an exposure switching unit 112 for independently switching whether or not the plurality of electron beams are to be irradiated on the wafer 44, and an electro-optic system including an wafer projection system 114 for adjusting direction and size of an image of a pattern which is transcribed on the wafer 44. The exposing unit 150 also includes a stage section including a wafer stage 46 for supporting the wafer 44 on which the pattern is transcribed, and a wafer stage driver 48 for driving the wafer stage 46.

The electron beam shaping unit 110 includes a plurality of electron guns 10 for producing electron beams, a first shaping member 14 having a plurality of openings which shape the cross-sectional shape of the electron beam by allowing the electron beam to pass through the openings, a second shaping member 22 serving as a splitting member having a plurality of splitting parts with a plurality of splitting openings which split the electron beam produced by the first shaping member 14 into a plurality of electron beams of different shapes, a shaping-blocking member 500 for blocking at least one electron beam out of the plurality of the split electron beams, a first multi-axis electron lens 16 for adjusting a focus of the electron beam by independently concentrating the plurality of the electron beams, and a first shaping deflector 18 and a second shaping deflector 20 for independently deflecting the plurality of the electron beams which have passed through the first shaping member 14.

The exposure switching unit 112 includes a second multi-axis electron lens 24 for adjusting a focus of an electron beam by independently concentrating a plurality of electron beams, an blanking electrode array 26 for independently switching whether or not the electron beam is to be irradiated on the wafer 44 by deflecting each of the plurality of electron beams independently, and an electron beam blocking unit 28 having a plurality of openings through which electron beams pass and blocking the electron beam deflected by the blanking electrode array 26. In another embodiment, the blanking electrode array 26 may be a blanking aperture array member.

The wafer projection system 114 includes a third multi-axis electron lens 34 for independently concentrating a plurality of electron beams and decreasing irradiated cross-sectional area of the electron beams, a fourth multi-axis electron lens 36 for independently concentrating a plurality of electron beams and adjusting a focus of the electron beams, a deflecting unit 38 for independently deflecting each of the plurality of electron beams on a desired location of the wafer 44, and a fifth multi-axis electron lens 52 serving as an object lens for the wafer 44 for independently concentrating the plurality of electron beams.

The control system 140 includes a general controlling unit 130 and an individual controlling unit 120. The individual controlling unit 120 includes an electron beam control section 80, a multi-axis electron lenses control section 82, a shaping deflecting control section 84, a blanking electrode array control section 86, a deflecting control section 92, and a wafer stage control section 96. The general controlling unit 130 may be, for example, a workstation generally controlling each of the controllers included in the individual controlling unit 120. The electron beam control section 80 controls the electron guns 10. The multi-axis electron lenses control section 82 controls currents provided to the first multi-axis electron lens 16, the second multi-axis electron lens 24, the third multi-axis electron lens 34, the fourth multi-axis electron lens 36, and the fifth multi-axis electron lens 52.

The shaping deflecting control section 84 controls the first shaping deflector 18 and the second shaping deflector 20. The blanking electrode array control section 86 controls voltage applied to deflection electrodes of the blanking electrode array 26. The deflecting control section 92 controls voltage applied to the deflection electrodes of a plurality of deflectors of the deflecting unit 38. The wafer stage control section 96 controls the wafer stage driver 48 so that the wafer stage 46 is caused to move to a predetermined location.

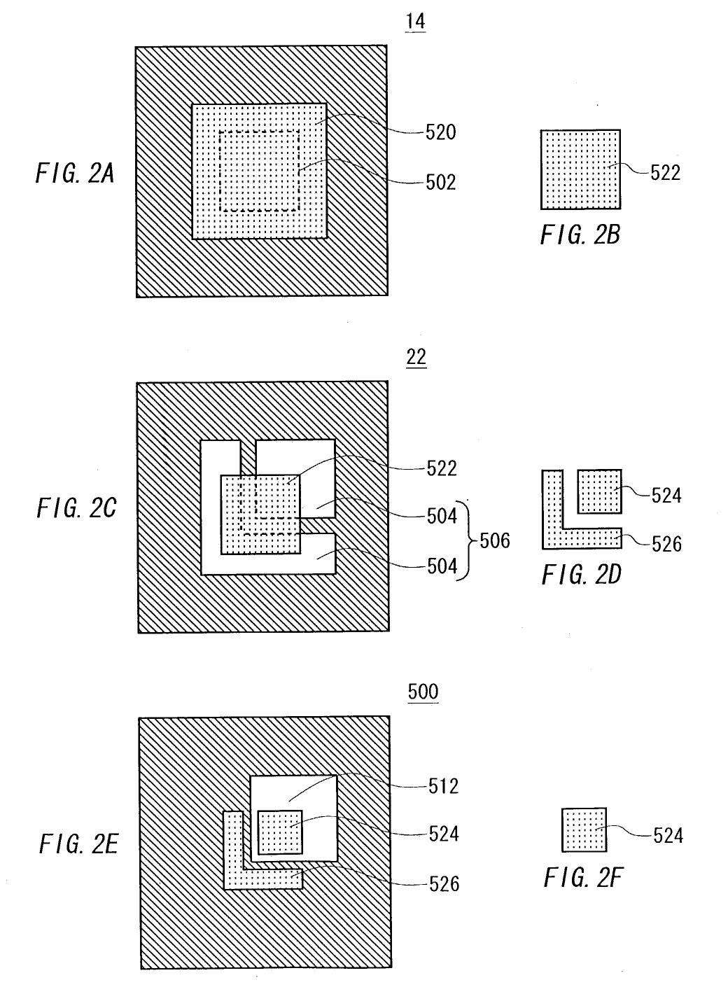

FIG. 2 shows the first shaping member 14, the second shaping member 22, the shaping-blocking member 500 and shapes of electron beams passing through each of the members. FIG. 2A shows a top view of the first shaping member 14 and a cross-sectional shape of the electron beam irradiated on the first shaping member 14. The first shaping member 14 includes a first shaping opening 502 which is an opening to shape the irradiated electron beam. It is preferable that the first shaping opening 502 has a rectangular shape, and an electron beam 520 irradiated on the first shaping member 14 in this embodiment is shaped into an electron beam 522 having a cross-sectional shape depicted in FIG. 2B.

FIG. 2C shows a top view of the second shaping member 22 and a cross-sectional shape of the electron beam irradiated on the second shaping member 22. The second shaping member 22 includes a splitting part 506 having a plurality of splitting openings 504 which split the electron beam 522 into a plurality of electron beams (524, 526) of different shapes. In this embodiment, at a bar formed by the plurality of splitting openings 504 in the second shaping member 22, at least a part of the irradiated electron beam 522 is blocked. Then the electron beam 522 irradiated on the second shaping member 22 is split into a plurality of electron beams including an electron beam 524 which is a exposure electron beam having a desired cross-sectional shape to be irradiated on the wafer 44, and an electron beam 526 having a different cross-sectional shape or a different cross-sectional area from the electron beam 524 as shown in FIG. 2D. It is preferable that at least one of the plurality of splitting openings 504 has a pair of substantially perpendicular sides. It is also preferable that at least one of the plurality of splitting openings 504 has substantially same shape and size as, or similar to, the first shaping opening 502 of the first shaping member 14. It is preferable that splitting openings having substantially same shape and size as, or similar to, the first shaping opening 502 are the splitting opening 504, through which the electron beam 524 to be irradiated on the wafer 44 passes, out of the plurality of electron beams (524, 526) which is split by the plurality of splitting openings 504. In this embodiment, the splitting opening 504 through which the electron beam 524 to be irradiated on the wafer 44 has rectangular shape.

FIG. 2E shows the shaping-blocking member 500 and a cross-sectional shape of an electron beam irradiated on the shaping-blocking member 500. The shaping-blocking member 500 includes a passing opening 512 which allows at least one of the plurality of electron beams split at the second shaping member 22 to pass through the passing opening 512. It is preferable that the passing opening 512 has a pair of substantially perpendicular sides. It is also preferable that the passing opening 512 has substantially same shape and size, or similar to, the splitting opening 504 at the second shaping member 22, through which the electron beam 524 to be irradiated on the wafer 44 passes. It is also preferable that the shaping-blocking member 500 is positioned subjacent to the second shaping member 22 and it is also preferable that the passing opening 512 is positioned to overlap with a bar formed between the splitting opening 504 through which the electron beam 524 to be irradiated on the wafer 44 passes and the other splitting opening 504 at the second shaping member 22. In this embodiment, the passing opening 512 has a rectangular shape and allows only the electron beam 524 to be irradiated on the wafer 44 out of a plurality of electron beams which is split by the second shaping member 22 to pass through the passing opening 512 (FIG. 2F). On another occasion, there may be a means further for independently deflecting respective split electron beams, which have passed through the second shaping member 22, between the second shaping member 22 and the shaping-blocking member 500 for adjusting irradiance positions of the split electron beams toward the second shaping member 22.

In the electron beam exposure apparatus 100 in this embodiment, an amount of irradiated electron beam of the second shaping member 22 can be reduced extremely by possessing the second shaping member 22 serving as a splitting member with the plurality of splitting openings 504 which split the irradiated electron beam into a plurality of electron beams of different shapes. Then the electron beams which have passed through the splitting openings 504 can be shaped into desired shapes accurately.

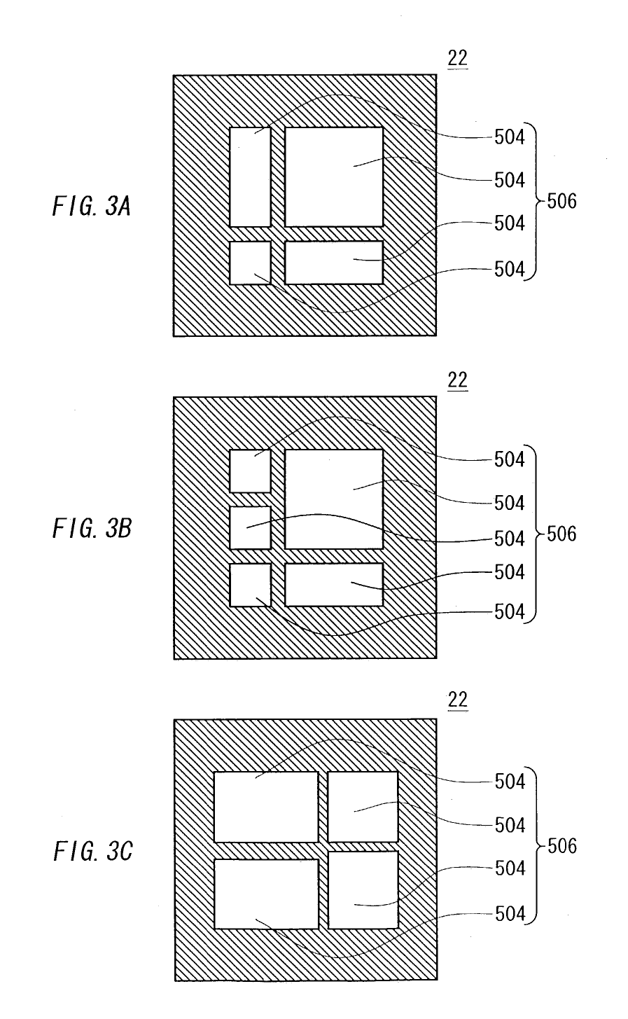

FIG. 3 shows other embodiments of the second shaping member 22. As shown in FIG. 3A and FIG. 3B, the splitting part 506 positioned at the second shaping member 22 may have splitting openings 504 to split further an electron beam which does not pass through the passing opening 512 (see FIG. 2). In this case, some of the splitting openings 504 out of the plurality of splitting openings 504 may be dummy openings through which an electron beam does not pass. It is preferable that the plurality of splitting openings 504 are positioned at the second shaping member 22 so that temperature of the splitting opening 504, through which an electron beam which passes through the passing opening 512 passes, is minimized. On another occasion, as shown in FIG. 3C, the plurality of splitting openings 504 may be positioned at different interval respectively. The splitting part 506 can adjust area of bar formed between the plurality of splitting openings 504 by possessing one (or some) of the splitting opening(s) 504 which splits further an electron beam which does not pass through the passing opening 512. Consequently, diffusion of heat produced by an electron beam irradiated on the second shaping member 22 can be adjusted. Then deformation of the splitting openings 504 caused by the heat of electron beam irradiated on the second shaping member 22 can be suppressed.

Referring to FIG. 1 and FIG. 2, the operation of the electron beam exposure apparatus 100 of the embodiment is described. First, the plurality of electron guns 10 produce a plurality of electron beams. The first shaping member 14 shapes a plurality of electron beam, which is produced by the plurality of electron guns 10 and irradiated on the first shaping member 14, by allowing the plurality of electron beams to pass through the plurality of openings positioned at the first shaping member 14. In another embodiment, a plurality of electron beams may be produced by further possessing a means for splitting an electron beam produced by the electron gun 10 into a plurality of electron beams.

The first multi-axis electron lens 16 independently concentrates a plurality of electron beams shaped into rectangular cross-sectional shape at the first shaping member 14 and independently adjusts focus of each of the electron beams toward the second shaping member 22. The first shaping deflector 18 respectively deflects a plurality of electron beams shaped into rectangular cross-sectional shape at the first shaping member 14 so that the plurality of electron beams are irradiated on desired locations of the second shaping member. It is preferable that the second shaping deflector 20 independently deflects each of a plurality of electron beams deflected at the first shaping deflector 18 to substantially perpendicular direction to the second shaping member 22.

The second shaping member 22 having the plurality of splitting openings 504 splits each of irradiated electron beams into a plurality of electron beams of different shapes (see FIG. 2D). Then the plurality of split electron beams are irradiated on the shaping-blocking member 500 and the shaping-blocking member 500 blocks at least one of the electron beams. Then the shaping-blocking member 500 allows electron beams which are not blocked by the shaping-blocking member out of the plurality of electron beams to pass through each of the passing openings 512. It is preferable that electron beams which pass through each of the passing openings 512 is electron beams shaped into the shape on which the electron beams are to be irradiated on the wafer 44. Another embodiment may include a means for further shaping electron beams which have passed through the passing opening 512, or a means for further blocking at least one of electron beams which have passed through the passing opening 512.

The second multi-axis electron lens 24 independently concentrates each of electron beams which have passed through the passing opening 512 and independently adjusts each of focus of electron beams toward the blanking electrode array 26. Then a plurality of electron beams, whose foci are adjusted respectively by the second multi-axis electron lens 24, pass through a plurality of apertures of the blanking electrode array 26.

The blanking electrode array control section 86 determines whether or not to apply voltage to the deflection electrodes which is located adjacent to each of the apertures of the blanking electrode array 26. The blanking electrode array 26 controls whether or not to allow an electron beam to be irradiated on the wafer 44 according to voltage applied to the deflection electrodes.

An electron beam which is not deflected by the blanking electrode array 26 passes through the third multi-axis electron lens 34. Then the third multi-axis electron lens 34 decreases cross-sectional area of an electron beam which passes through the third multi-axis electron lens 34. The decreased electron beam passes through an opening of the electron beam blocking unit 28. Then the electron beam blocking unit 28 blocks an electron beam deflected by the blanking electrode array 26. The electron beam which has passed through the electron beam blocking unit 28 is irradiated on the fourth multi-axis electron lens 36. Then the fourth multi-axis electron lens 36 independently concentrates each of irradiated electron beams and adjusts focus of each of electron beams toward the deflecting unit 38. Electron beams whose foci are adjusted by the fourth multi-axis lens 36 are irradiated on the deflecting unit 38.

A plurality of deflectors of the deflecting unit 38 independently deflects each of electron beams irradiated on the deflecting unit 38 to the location where the electron beam is to be irradiated on the wafer 44 according to instructions from the deflecting control section 92. The fifth multi-axis electron lens 52 adjust focus of each of electron beam, which passes through the fifth multi-axis electron lens 52, toward the wafer 44. Then each of electron beams, having cross-sectional shape in which the electron beam is to be irradiated on the wafer 44, is irradiated on a desired position where the electron beam is to be irradiated on the wafer 44.

During an exposure process, it is preferable that the wafer stage driver 48 drives the wafer stage 46 to a certain direction based on instructions from the wafer stage control section 96. Then a desired circuit patterns can be exposed to the wafer 44 by shaping a cross-sectional shape of an electron beam into a shape in which the electron beam is to be irradiated on the wafer 44 in response to the movement of the wafer 44, by determining apertures which allow electron beams irradiated on the wafer 44 to pass through, and by deflecting each of electron beams to location where the electron beams are to be irradiated on the wafer 44 by the deflecting unit 38.

Although the present invention has been described by way of exemplary embodiment, the scope of the present invention is not limited to the foregoing embodiment. Various modifications in the foregoing embodiment may be made when the present invention defined in the appended claims is enforced. It is obvious from the definition of the appended claims that embodiments with such modifications also belong to the scope of the present invention.

It is obvious from foregoing explanation that the present invention can provide an electron beam exposure apparatus which can shape a cross-sectional shape of electron beam accurately.

What is claimed is:

1. An electron beam exposure apparatus which exposes patterns on a wafer by an electron beam, comprising:
an electron beam producing unit which produces said electron beam,
a splitting member comprising splitting parts with a plurality of splitting openings which split said electron beam into a plurality of electron beams of different shapes; and
a blocking member which blocks at least one electron beam out of said plurality of electron beams.

2. The electron beam exposure apparatus as claimed in claim 1 further comprising a shaping member with shaping opening which shapes said electron beam produced at said electron beam producing unit into rectangular shape; and
wherein said splitting member splits said electron beam shaped into rectangular shape.

3. The electron beam exposure apparatus as claimed in claim 1, wherein said splitting part further splits an electron beam which is not blocked by said blocking member out of said plurality of electron beams.

4. The electron beam exposure apparatus as claimed in claim 1, wherein said blocking member comprises an passing opening through which an electron beam to be irradiated on said wafer out of said plurality of electron beams passes.

5. The electron beam exposure apparatus as claimed in claim 4, wherein said electron beam producing unit produces a plurality of said electron beams,
said splitting member comprises said splitting parts respectively in an area where said plurality of electron beams at said splitting member are irradiated; and
said blocking member comprises a plurality of said passing openings in an area where split said plurality of electron beams, which respectively correspond to a plurality of electron beams produced at said electron beam producing unit, are irradiated.

6. An electron beam exposure method exposing patterns on a wafer using an electron beam, comprising the steps of:
producing said electron beam,
splitting said electron beam into a plurality of electron beams having different shape respectively; and
blocking at least one electron beam out of said plurality of electron beams.
